(19) United States
(12) Patent Application Publication
(10) Pub. No.: US 2023/0288913 A1
(43) Pub. Date: Sep. 14, 2023

(54) Placement method for accurately positioned placement of large components on a target region of a substrate, and associated placement apparatus

(71) Applicant: ERSA GmbH, Wertheim (DE)

(72) Inventors: Sai-Krishna Vuppala, Wertheim (DE); Aparna Palla, Wertheim (DE); Marius Klein, Obernburg (DE)

(73) Assignee: ERSA GmbH, Wertheim (DE)

(21) Appl. No.: 18/118,334

(22) Filed: Mar. 7, 2023

(30) Foreign Application Priority Data
Mar. 8, 2022 (DE) 10 2022 105 380.6

(51) Int. Cl. G05B 19/4099; G06T 7/73; B25J 9/16

(52) U.S. Cl. CPC G05B 19/4099; G06T 7/74; B25J 9/1697; G06T 2207/30141; G05B 2219/45031

(57) ABSTRACT

Placement method for the accurately positioned placement of large components with pins on a target region of a substrate, in particular a printed circuit board, and placement apparatus for this purpose.

### CROSS-REFERENCE TO RELATED APPLICATIONS

The present application claims priority to German Patent Application No. 10 2022 105 380.6, filed Mar. 8, 2022, the disclosure of which is incorporated herein by reference in its entirety.

### BACKGROUND

The invention relates to a placement method for the accurately positioned placement of components with pins on a target region of a substrate, such as in particular a printed circuit board. The invention also relates to a placement apparatus for placing such components.

The components are generally electrical or electronic components, such as memory modules, microprocessors, inverters, VCSEL components, photodiodes, MEMS components or chip-on-glass components. The substrate on which the components are placed has contact points corresponding to the pins of the components, it being necessary for an accurately positioned alignment during the placement of the components on the substrate to be carried out in such a way that the respective pins of the component come into contact with the contact points of the substrate corresponding thereto.

The contact points are preferably conductive connections (pads) applied to the surface of the substrate. The components are placed on the substrate such that one pin in each case comes to rest on an associated pad and is attached there by means of reflow soldering (SMT—surface-mounted technology). The pins can also be contact feet. However, it is also conceivable for the contact points to be formed as contacts surrounding holes in the substrate, the pins of the components then being inserted into the holes for contacting with the contact points (THT—through-hole technology).

A method for the accurately positioned placement of components and an associated placement apparatus are known from EP 2 989 872 B1.

It is known from EP 2 989 872 B1 to grip a component and to guide it via an image acquisition system which captures an image of the component. A further image acquisition system captures an image of the target region on the substrate. An evaluation or control unit evaluates the images and determines a position deviation which is compensated before the component is placed on the substrate.

WO 97/02708 discloses a placement method in which the component is first gripped and moved into the region above the target region. An image acquisition system is then moved into the region between the gripped component and the target region in order to detect on the one hand the component and on the other hand the target region, the component and the target region each lying in the detection region of the image acquisition system. A plurality of images can be generated using the image acquisition system, in particular of diagonally opposite corner regions of the component or of the target region. From the acquired images, a position deviation between the component and the target region is then calculated, which is compensated before the component is set on the target region.

A placement apparatus which has the features of the preamble of claim 1 is known from the reworking apparatus HR600XL, marketed by the applicant at the time of filing. In this case, a first image acquisition system, arranged in a fixed or stationary manner, is provided below a support surface onto which the component is placed for the detection of the pins. A second image acquisition system is provided above the substrate and captures the target region.

By means of this apparatus, components can be gripped and placed, which have a dimension, extending in parallel with the substrate, of up to approximately 60×60 mm. When the support surface and the target surface have been captured, the detection regions of the image acquisition systems are able to capture such large regions with sufficiently high accuracy. Since larger regions cannot be captured with sufficient accuracy, it is problematic to automatically place, in an accurately positioned manner, components whose dimensions are greater than 60×60 mm.

In order to nevertheless be able to align and place such large components, it would be conceivable to use image acquisition systems having larger detection regions. However, this is associated with disadvantages, in particular with higher costs for the hardware, since higher resolutions of the generated and processed images are associated with the larger detection regions. In addition, a complicated adjustment of the software used to image acquisition systems having larger detection regions and higher resolutions is required.

### SUMMARY OF THE INVENTION

The object of the present invention is therefore to provide a placement method and placement apparatus by means of which comparatively large components can be aligned and placed in a simple manner and nevertheless in a functionally reliable manner.

This object is achieved by a placement method for the accurately positioned placement of components comprising pins on a target region of a substrate according to claim 1. The method is here carried out by means of a placement apparatus.

Such a placement apparatus comprises a clamping device for clamping a substrate. The substrate can in particular be a printed circuit board.

Furthermore, a support surface extending in the x, y directions, i.e. in parallel with the plane in which the substrate is located, is provided for depositing components to be placed. The support surface is transparent, in particular made of glass, and in particular is arranged in a fixed or stationary manner on the apparatus. Said surface can be designed as a type of light dome which is illuminated in such a way that the component is sufficiently illuminated through the glass plate from below, i.e. from the side on which the pins are provided.

Furthermore, provision is made for a first image acquisition system, likewise in particular arranged in a fixed manner, for detecting pins of components placed on the support surface. The pins illuminated from below can be detected using the first image acquisition system. The image acquisition system is preferably located below the support surface. The first image acquisition system can be designed as a camera, in particular as a video camera or CCD camera. It has been shown that a monochrome camera has advantages here.

Furthermore, provision is made for a second image acquisition system for detecting contact points present in the target region on a target surface extending in the x, y directions. In this case, the target surface also extends in parallel with the plane in which the substrate is located. The second image acquisition system is preferably arranged so as to be movable relative to the clamped substrates in at least the x, y directions, in particular also in the z direction, i.e. perpendicularly to a plane spanning the x and y directions. The second image acquisition system can be designed as a camera, in particular as a video camera or CCD camera. It has been shown that a color camera is advantageous here.

Furthermore, a gripping unit is provided, which is designed to pick up the component, to move the component in the x, y and z directions, to rotate the component about the z direction, and to set down the component on the target region in an accurately positioned manner. The gripping unit comprises in particular a movable vacuum pipette which sucks up the component for gripping by means of a vacuum.

Furthermore, a control unit is provided which is designed in particular to control the two image acquisition systems and the gripping unit, and to evaluate the images acquired by the image acquisition systems.

In this case, the first method according to the invention according to claim 1 provides the following steps:
(a) Gripping a component whose dimensions in the x and y directions are greater than the detection region of the first image acquisition system in the support surface and/or the second image acquisition system in the target surface,
(b) Depositing the component on the support surface such that a prespecifiable region of the component with pins (in the following ROI component region, where ROI: region of interest) lies within the detection region of the first image acquisition system,
(c) Detecting the pins of the component in this region of the component (ROI component region) using the first image acquisition system, and determining therefrom an item of pin detection information,
(d) Detecting contact points in a region of the target region (ROI target region) corresponding to the prespecifiable region of the component using the second image acquisition system, and determining therefrom an item of contact point detection information,
(e) Superimposing the pin detection information and the contact point detection information, and determining a deviation of the pin detection information from the contact point detection information,
(f) Determining a difference vector for displacing the component in the x,y direction, and an angle of rotation for rotating the component about the z direction, such that the deviation is compensated,
(g) Moving the component along the difference vector and rotating the component about the rotation angle, and
(h) Placing the component, using the gripping unit, on the target region of the substrate.

The first method according to the invention thus offers the advantage that components which have a dimension in the x and y directions which is greater than the detection region of the first and/or the second image acquisition system can be placed in an accurately positioned manner. In this case, the components can theoretically be of any desired size, since it is not necessary, according to the method according to the invention, to bring the components fully into the detection region of the image acquisition systems. The detection of only one prespecifiable ROI component region (ROI: region of interest) using the first image acquisition system, which is advantageously provided below the support surface, is sufficient. In other words, only the ROI component region is captured, and not the entire component. The ROI component region can in particular already be defined prior to the gripping of the component. As soon as the type of component to be gripped and placed is known, this ROI component region can be prespecified or defined.

After the first image acquisition system has captured the ROI component region, an item of pin detection information is determined therefrom. This pin detection information can, for example, be reproduced on a screen, and the detected pins can be displayed.

Using the second image acquisition system, contact points of a prespecifiable region of the component (ROI target region) are detected, this ROI target region corresponding to the ROI component region. The second image acquisition system, which is preferably arranged above the substrate, consequently captures only the ROI target region of the target region and not the entire target region. The second image acquisition system can thus be designed such that its detection region is much smaller than the entire target region. An item of contact point detection information is then determined from the images acquired using the second image acquisition system. This contact point detection information can also be displayed on a screen, it being possible in particular for the contact points within the ROI target region to be reproduced.

Unlike the HR600XL system marketed by the applicant, consequently not the entire component in each case (using the first image acquisition system) and neither the entire target region (using the second image acquisition system) is captured, but only the prespecifiable ROI component region and the ROI target region. The ultimate size of the component to be placed and the target region are here irrelevant; what is crucial is that the ROI component region and the ROI target region are selected so as to correspond to one another, and that the information acquired therefrom is processed.

By superimposing the pin detection information and the contact point detection information, position deviations between the target surface and the component located on the support surface can consequently be determined using suitable image evaluation software.

Furthermore, a difference vector and a rotation angle can be determined, in order to compensate for the position deviation.

Furthermore, the gripped component is moved along the difference vector and rotated about the angle of rotation, such that the position deviation is compensated.

Finally, the component can be accurately positioned on the target region of the substrate, using the gripping unit.

It has also been found that it is advantageous if the component has one or more corner regions, the ROI component region being a defined corner region of the component, and if the target region has a plurality of corner regions, a prespecifiable ROI target region being a corner region of the target region corresponding to the corner region of the component. This has the advantage that corner regions are comparatively easily detectable and also differentiable.

Furthermore, it is advantageous if the component is identified before, during or after the gripping according to step (a), and if the prespecifiable ROI component region is automatically read out of a database. This has the advantage that the process can be carried out in a fully automated manner: the component is detected, the ROI component region is read out, and the component is placed, in accordance with step (a), on the support surface, such that the ROI component region can be detected by the first image acquisition system.

In this case, the gripping according to step (a) can take place either manually or also automatically.

Advantageously, the gripping according to step (a) takes place in such a way that the component is gripped in the region or above the region of its geometric center of gravity. This has the advantage that the component can be gripped at a comparatively small point, for example by means of a vacuum, the component at least largely maintaining its orientation which is present in parallel with the plane of the support surface. Tilting or pivoting away of the component due to an off-center gripping is thereby prevented.

Furthermore, it is advantageous if the geometric center of gravity of the respective component is determined on the basis of the component size information and/or mechanically, for example by means of a suitable device.

The above-mentioned object is also achieved by a second placement method according to the invention having the features of claim 7. Such a second method according to the invention provides the following steps:
(a) Gripping a component whose dimensions in the x and y directions are greater than the detection region of the first image acquisition system in the support surface, and/or the second image acquisition system in the target surface,
(b) Depositing the component on the support surface in such a way that a prespecifiable region of the component comprising pins (ROI component region) is present in the detection region of the first image acquisition system, and detecting the pins of the component in this region using the first image acquisition system,
(c) Moving the component such that a second region adjoining the first region lies within the detection region of the first image acquisition system, and detecting the pins of the component in this region using the first image acquisition system,
(d) Repeating steps (b) and (c) until the majority or all of the pins of the component are detected,
(e) Determining an item of pin detection information from the acquired images of the component,
(f) Detecting contact points in a first region of the target region (ROI target region) corresponding to the prespecifiable first region of the component, using the second image acquisition system,
(g) Moving the second image acquisition system such that a second region of the target region adjacent to the first region is captured, and detecting the contact points in this region using the second image acquisition system,
(h) Repeating steps (f) and (g) until the majority or all of the contact points of the target region are detected,
(i) Determining an item of contact point detection information from the acquired images of the target region,
(j) Superimposing the pin detection information and the contact point detection information, and determining a deviation of the pin detection information from the pin detection information,
(k) Determining a difference vector for displacing the component in the x,y direction, and an angle of rotation for rotating the component about the z direction, such that the deviation is compensated,
(l) Moving the component along the difference vector and rotating the component about the rotation angle, and
(m) Placing the component, using the gripping unit, on the target region of the substrate.

By repeating steps (b) and (c) in step (d), and steps (f) and (g) in step (h), a larger overall image can be created from the individual acquired images by means of a type of stitching using suitable image processing software. This larger overall image can then cover at least the majority of the pins of the respective component or the majority of the contact points of the respective target region, or also all pins or also all contact points. By corresponding superimposition of the pin detection information and the contact point detection information it is possible, as already described, for a deviation to be determined and a difference vector and a rotation angle for compensating the deviation to be determined. Due to this information, the component can then be gripped, oriented and placed accordingly. According to the first method according to the invention, components which are larger than the detection region of the first image acquisition system can also be oriented and placed in an accurately positioned manner using this second method according to the invention.

The object mentioned at the outset is also achieved by a third method according to the invention having the features of claim 8. This third method according to the invention comprises the following steps:
(a) Gripping a component whose dimensions in the x and y directions are greater than the detection region of the first image acquisition system in the support surface and/or the second image acquisition system in the target surface,
(b) Depositing the component on the support surface such that a prespecifiable first region of the component, comprising pins, lies within the detection region of the first image acquisition system,
(c) Detecting two or more prespecifiable characteristic pins using the first image acquisition system, and determining therefrom an item of pin detection information,
(d) Detecting contact points in a ROI target region corresponding to the characteristic pins, using the second image acquisition system, and determining an item of contact point detection information therefrom,
(e) Superimposing the pin detection information and the contact point detection information, and determining a deviation of the pin detection information from the pin detection information,
(f) Determining a difference vector for displacing the component in the x,y direction, and an angle of rotation for rotating the component about the z direction, such that the deviation is compensated,
(g) Moving the component along the difference vector and rotating the component about the rotation angle, and
(h) Placing the component, using the gripping unit, on the target region of the substrate.

This third method according to the invention is particularly suitable when characteristic pins are provided which can be detected by means of the first image acquisition system, or if characteristic contact points are provided which can be detected by means of the second image acquisition system. In this case, it is conceivable that in total two or more such prespecifiable pins and contact points are defined and prespecified, which are ultimately used by the image acquisition systems for the respective position determination and position orientation. As a result of this, too, components which are larger than the detection region of the in particular first image acquisition system can also be reliably oriented and placed.

The object mentioned at the outset is also achieved by a placement apparatus according to claim 9. Such a placement apparatus is designed in particular such that the control unit is configured to carry out one of the methods according to the invention, such that components can be placed on the substrate which are larger in the x and y directions than the detection region of the first image acquisition system in the support surface and/or than the detection region of the second image acquisition system in the target surface.

In such a placement apparatus, the first image acquisition system is preferably arranged in a fixed or stationary manner below the support surface, and the second image acquisition system is arranged above the substrate, so as to be displaceable, in particular in the x, y and z directions.

It is further advantageous if the gripping unit has a gripping finger which is displaceable in the x, y and z directions and which is also rotatable about the z direction, and if the gripping finger is configured to receive the component, to rotate it about the z direction, and to deposit it on the target region.

It is also advantageous if the first image acquisition system and the second image acquisition system are each formed by a separate camera. However, it can also be provided that the two image acquisition systems are implemented in the same camera, it then being possible for splitting optical systems, in particular comprising periscopes, to be provided for separating the detection regions.

### BRIEF DESCRIPTION OF THE DRAWINGS

Further details and advantages of the invention are described in the following embodiments and shown in the figures,

in which:

FIG. 1 shows a placement apparatus according to the invention;

FIG. 2 is a detail of the placement apparatus according to FIG. 1 comprising a support surface on which a component to be placed lies;

FIG. 3 is an enlarged detail of the placement apparatus according to FIG. 1, showing the substrate and a target surface;

FIGS. 4, 5 and 6 show different method sequences according to the invention.

### DETAILED DESCRIPTION

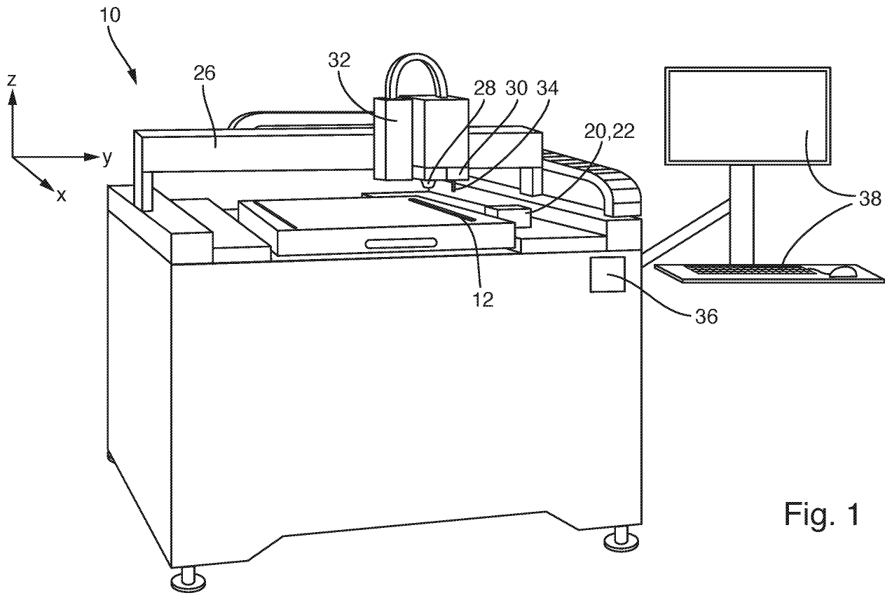

FIG. 1 shows a placement apparatus 10, by means of which components with pins can be placed on a target region of a substrate, in particular a printed circuit board. Using the placement apparatus 10, the placed components can also be soldered by means of the reflow soldering method.

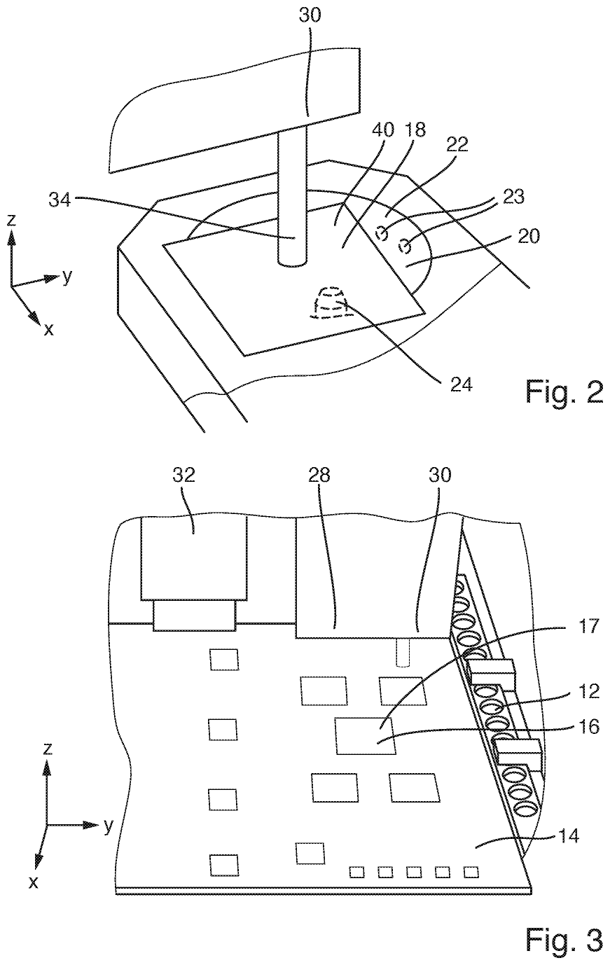

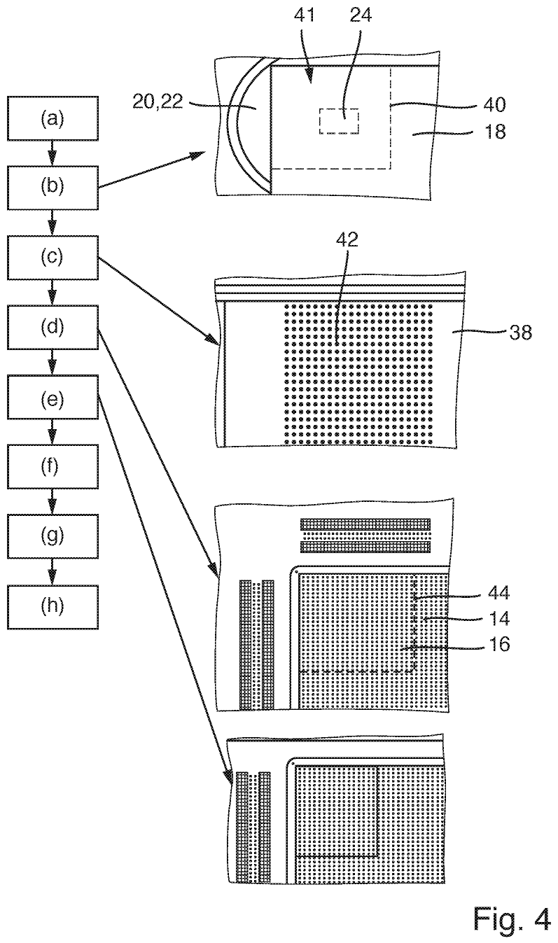

The placement apparatus 10 comprises a clamping device 12 for clamping a substrate 14, as is shown for example in FIG. 3. A target region 16 comprising a target surface 17 which extends in the x, y directions is provided on the substrate 14. The target region 16 has a large number of comparatively small contact points, on which a component 18, as shown in FIG. 2, can be placed in an accurately positioned manner.

In FIG. 2, the component 18 is located on a support surface 20, the pins of the component 18 resting on the support surface 20. The support surface 20 is made of glass and closes a light dome 22 upwards. In the light dome 22, illumination means 23 are provided which illuminate the light dome 22 and illuminate the component 18 or the pins thereof. The light dome 22 together with the support surface 20 is arranged in a fixed manner on the placement apparatus 10, which becomes clear from FIG. 1.

A first image acquisition system 24 in the form of a CCD monochrome camera is provided within the light dome 22 or on its floor. The image acquisition system, which lies below the component 18, is indicated by dashed lines in FIG. 2. The pins of the component 18 in the detection region of the image acquisition system 24 can be detected by means of the first image acquisition system 24.

As is clear from FIG. 1, the placement apparatus 10 has a gantry 26 on which a second image acquisition system 28, a gripping unit 30 comprising a gripping finger 34, and a soldering device 32 are arranged. The gantry 26 can be moved along a guide in the x direction. The image acquisition system 28, the gripping unit 30 and the soldering device 32 can be moved on the gantry 26 in the y direction running perpendicularly thereto. Furthermore, at least the gripping finger 34 of the gripping unit 30 can also be raised and lowered in the z direction extending perpendicularly to the x, y directions.

The image acquisition system 28 is used to detect contact points present in the target region 16 shown in FIG. 3.

In this case, the support surface 20 is preferably located in the same plane as the target surface 17. This has the advantage that transformations of the images from the image acquisition system 24, 28 can be carried out comparatively easily. However, it is also conceivable for the support surface 20 to lie in a different plane from the target surface 17. Transformations of the captured images are then correspondingly required.

The gripping unit 30 comprising the gripping finger 34 serves to pick up the component 18 and to deposit it on the support surface 20. Furthermore, it is used to pick up the deposited component 18 from the support surface 20 and to move it towards the target region 16, in order to deposit it there in an accurately positioned manner. In this case, the gripping preferably takes place in the region of or above the geometric center of gravity of the component 18.

A control unit 36 is provided for controlling the two image acquisition systems 24 and 28, the gripping unit 30 and the soldering unit 32. In order to communicate with the control unit 36, an input and output device 38 in the form of a display with a keyboard is provided.

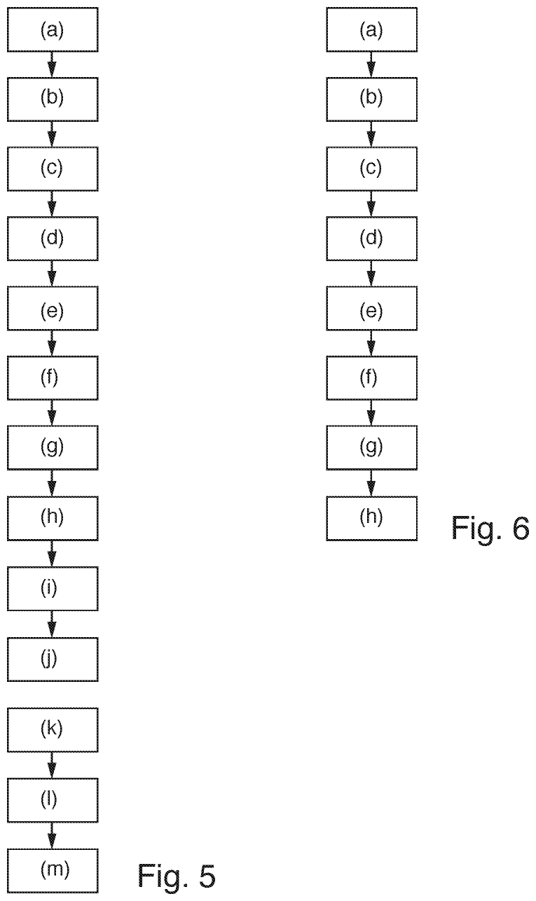

As is clear from FIG. 2, the component shown there is larger than the detection region of the camera 24 present in the light dome 22. In order nevertheless to be able to place such a large component 18 in an accurately positioned manner on the target region, the placement apparatus 10 is configured such that it can carry out different placement methods, the steps of which are shown in FIGS. 4, 5 and 6.

According to a first placement method, the following steps are carried out as shown in FIG. 4:
(a) Gripping the component 18, the dimensions of which in the x and y directions are greater than the detection region of the first image acquisition system 24 in the support surface 20 and/or of the second image acquisition system 28 in the target surface 17.
(b) Placing the component 18 on the support surface 20 such that the prespecifiable, ROI component region 40 comprising pins lies within the detection region of the first image acquisition system on 24. According to FIG. 4(b), the ROI component region 40 which is captured by the image acquisition system 24 is prespecified as the left-hand upper corner region 41 of the component 18.
(c) Detecting the pins of the component 18 in this ROI component region 40 using the first image acquisition system 24, and determining therefrom an item of pin detection information 42, and displaying said pin detection information 42 on the screen 38. By means of suitable image processing software, the image acquired by the image acquisition system 24 is processed and displayed.
(d) Detecting contact points 48 in a ROI target region 44 corresponding to the ROI component region 40, using the second image acquisition system 28. FIG. 4(d) shows the substrate with the ROI target region 44, which is formed by a left-hand upper corner region of the target region 16. From this, the contact point detection information is created.
(e) Superimposing the pin detection information and the contact point detection information, which is shown in FIG. 4(d). A deviation of the pin detection information from the contact point detection information is then determined.
(f) Determining a difference vector for displacing the component 18 in the x,y direction, and an angle of rotation for rotating the component 18 about the z direction, such that the deviation is compensated.
(g) Moving the gripped component 18 along the difference vector and rotating the component 18 about the angle of rotation, and
(h) Placing the component 18, using the gripping unit 30, on the target region 16 of the substrate (14).

According to a second placement method, the following steps, as shown in FIG. 5, are carried out:
(a) Gripping a component 18 whose dimensions in x and y directions are greater than the detection region of the first image acquisition system 24 in the support surface 20 and/or of the second image acquisition system 28 in the target surface 17,
(b) Depositing the component 18 on the support surface 20 such that a prespecifiable ROI component region with pins lies within the detection region of the first image acquisition system 24, and detecting the pins of the component 18 in this ROI component region using the first image acquisition system 24,
(c) Moving the component 18 such that a ROI component region adjoining the first ROI component region lies within the detection region of the first image acquisition system 24, and detecting the pins of the component 18 in this ROI component region using the first image acquisition system 24,
(d) Repeating steps b and c until the majority or all of the pins of the component 18 are detected,
(e) Determining an item of pin detection information from the acquired images of the component 18,
(f) Detecting contact points in a first ROI target region corresponding to the prespecifiable first ROI component region using the second image acquisition system 28,
(g) Moving the second image acquisition system 28 such that a second ROI target region adjoining the first ROI target region is captured, and detecting the contact points of this ROI target region using the second image acquisition system 28,
(h) Repeating steps f and g until the majority or all of the contact points of the target region 16 are detected,
(i) Determining an item of contact point detection information from the acquired images of the target region,
(j) Superimposing the pin detection information and the contact point detection information, and determining a deviation of the pin detection information from the contact point detection information,
(k) Determining a difference vector for displacing the component 18 in the x,y direction, and an angle of rotation for rotating the component 18 about the z direction such that the deviation is compensated,
(l) Moving the component 18 along the difference vector and rotating the component 18 about the angle of rotation, and
(m) Placing the component 18, using the gripping unit, on the target region 16 of the substrate.

According to a third placement method, the following steps, as shown in FIG. 5, are carried out:
(a) Gripping a component 18 whose dimensions in x and y directions are greater than the detection region of the first image acquisition system 24 in the support surface 20 and/or of the second image acquisition system 28 in the target surface 17,
(b) Depositing the component 18 on the support surface 20 such that a prespecifiable first region of the component 18, with pins, lies within the detection region of the first image acquisition system 24,
(c) Detecting two or more prespecifiable characteristic pins using the first image acquisition system 24, and determining therefrom an item of pin detection information,
(d) Detecting contact points in a region of the target region of ROI target region corresponding to the characteristic pins, using the second image acquisition system 28, and determining an item of contact point detection information therefrom,
(e) Superimposing the pin detection information and the contact point detection information, and determining a deviation of the pin detection information from the contact point detection information,
(f) Determining a difference vector for displacing the component 18 in the x,y direction, and an angle of rotation for rotating the component 18 about the z direction, such that the deviation is compensated,
(g) Moving the component 18 along the difference vector and rotating the component 18 about the angle of rotation, and
(h) Placing the component 18, using the gripping unit 30, on the target region of the substrate.

As a result of the described methods, it is consequently possible to place, in an accurately positioned manner, components 18 which are of a size that is significantly greater than the detection region of the first image acquisition system 24. This has the advantage, inter alia, that existing apparatuses can be used, which are to be set up according to the respective method according to the invention.

What is claimed is:

1. Placement apparatus used for the accurately positioned placement of components with pins on a target region of a substrate comprising:
a clamping device for clamping a substrate,
a support surface extending in the x, y directions for the deposition of components to be placed,
a first image acquisition system for detecting pins of components deposited on the support surface,
a second image acquisition system for detecting contact points present on the target region in a target surface extending in the x, y directions,
a gripping unit, which is configured to receive the component, to move the component in the x, y and z directions, to rotate the component about the z direction, and to deposit the component in an accurately positioned manner on the target region, and
a control unit which is designed to control the image acquisition systems, to evaluate the images acquired by the image acquisition systems, and to control the gripping unit,
wherein the placement apparatus is adapted for:
(a) gripping a component whose dimensions in the x and y directions are greater than the detection region of the first image acquisition system in the support surface and/or of the second image acquisition system in the target surface,
(b) depositing the component on the support surface such that a prespecifiable ROI component region comprising pins lies within the detection region of the first image acquisition capturing system,
(c) detecting the pins of the component in this ROI component region using the first image acquisition system, and determining therefrom an item of pin detection information,
(d) detecting contact points in a ROI target region corresponding to the ROI component region, using the second image acquisition system, and determining therefrom an item of contact point detection information,
(e) superimposing the pin detection information and the contact point detection information, and determining a deviation of the pin detection information from the contact point detection information,
(f) determining a difference vector for displacing the component in the x,y direction, and an angle of rotation for rotating the component about the z direction, such that the deviation is compensated,
(g) moving the component along the difference vector and rotating the component about the angle of rotation, and
(h) placing the component, using the gripping unit, on the target region of the substrate.

2. The placement apparatus according to claim 1, wherein the component has one or more corner regions, wherein the prespecifiable ROI component region is a defined corner region of the component, wherein the target region has a plurality of corner regions, and wherein the prespecifiable ROI target region is a corner region of the target region corresponding to the corner region of the component.

3. The placement apparatus according to claim 1, wherein the prespecifiable ROI component region is automatically read out of a database.

4. The placement apparatus according to claim 1, wherein the placement apparatus is adapted for manual gripping.

5. The placement apparatus according to claim 1, wherein the placement apparatus to adapted to grip in the region of or above the geometric center of gravity of the component.

6. The placement apparatus according to claim 5, wherein the geometric center of gravity of the respective component is determined on the basis of the component size information and/or mechanically.

7. Placement method for the accurately positioned placement of components with pins on a target region of a substrate, wherein the method comprises the following steps:
a. providing a placement apparatus comprising a clamping device for clamping a substrate, a support surface extending in the x, y directions for the deposition of components to be placed, a first image acquisition system for detecting pins of components deposited on the support surface, a second image acquisition system for detecting contact points present on the target region in a target surface extending in the x, y directions, a gripping unit, which is configured to receive the component, to move the component in the x, y and z directions, to rotate the component about the z direction, and to deposit the component in an accurately positioned manner on the target region, and a control unit which is designed to control the image acquisition systems, to evaluate the images acquired by the image acquisition systems, and to control the gripping unit;
b. gripping a component whose dimensions in the x and y directions are greater than the detection region of the first image acquisition system in the support surface and/or of the second image acquisition system in the target surface,
c. depositing the component on the support surface such that a prespecifiable ROI component region comprising pins lies within the detection region of the first image acquisition system, and detecting the pins of the component in this ROI component region (40) using the first image acquisition system,
d. moving the component such that a second ROI component region adjoining the first ROI component region lies within the detection region of the first image acquisition system, and detecting the pins of the component in this second ROI component region using the first image acquisition system,
e. repeating steps (c) and (d) until the majority or all of the pins of the component are detected,
f. determining an item of pin detection information from the acquired images of the component,
g. detecting contact points in a first ROI target region corresponding to the prespecifiable first ROI component region, using the second image acquisition system,
h. moving the second image acquisition system such that a second ROI target region adjoining the first ROI target region is captured, and detecting the contact points of this ROI target region using the second image acquisition system,
i. repeating steps (g) and (h) until the majority or all of the contact points of the target region are detected,
j. determining an item of contact point detection information from the acquired images of the target region,
k. superimposing the pin detection information and the contact point detection information, and determining a deviation of the pin detection information from the contact point detection information,
l. determining a difference vector for displacing the component in the x,y direction, and an angle of rotation for rotating the component about the z direction, such that the deviation is compensated,
m. moving the component along the difference vector and rotating the component about the angle of rotation, and
n. placing the component, using the gripping unit, on the target region of the substrate.

8. Method according to the preamble of claim 1, according to claim 1 or according to any one of the preceding claims, characterized in that the method comprises the following steps:
a. providing a placement apparatus comprising a clamping device for clamping a substrate, a support surface extending in the x, y directions for the deposition of components to be placed, a first image acquisition system for detecting pins of components deposited on the support surface, a second image acquisition system for detecting contact points present on the target region in a target surface extending in the x, y directions, a gripping unit, which is configured to receive the component, to move the component in the x, y and z directions, to rotate the component about the z direction, and to deposit the component in an accurately positioned manner on the target region, and a control unit which is designed to control the image acquisition systems, to evaluate the images acquired by the image acquisition systems, and to control the gripping unit;
b. gripping a component whose dimensions in the x and y directions are greater than the detection region of the first image acquisition system in the support surface and/or of the second image acquisition system in the target surface,
c. depositing the component on the support surface such that a prespecifiable first ROI component region comprising pins lies within the detection region of the first image acquisition system,
d. detecting two or more prespecifiable characteristic pins using the first image acquisition system, and determining therefrom an item of pin detection information,
e. detecting contact points in a ROI target region corresponding to the characteristic pins, using the second image acquisition system, and determining an item of contact point detection information therefrom,
f. superimposing the pin detection information and the contact point detection information, and determining a deviation of the pin detection information from the contact point detection information,
g. determining a difference vector for displacing the component in the x,y direction, and an angle of rotation for rotating the component about the z direction, such that the deviation is compensated,
h. moving the component along the difference vector and rotating the component about the angle of rotation, and
i. placing the component, using the gripping unit, on the target region of the substrate.

9. Placement apparatus for the accurately positioned placement of components with pins on a target region of a substrate, comprising
a clamping device for clamping a substrate,
a support surface extending in the x, y directions for the deposition of components to be placed,
a first image acquisition system for detecting pins of components deposited on the support surface in a plane extending in the x, y directions,
a second image acquisition system for detecting contact points present in the target region in a plane extending in the x, y directions,
a gripping unit which is configured to pick up the component, to rotate the component about the z direction, and to deposit the component on the target region in an accurately positioned manner, and
a control unit which is designed to control the image acquisition systems, to evaluate the images captured by the image acquisition systems, and to control the gripping unit,
characterized in that the control unit is adapted to carry out a placement method, such that components can be placed on the substrate which are larger in the x and y directions than the detection region of the first image acquisition system in the support surface and/or than the detection region of the second image acquisition system in the target surface.

10. The placement apparatus according to claim 9, wherein the first image acquisition system is arranged in a fixed manner below the support surface, and wherein the second image acquisition system is arranged displaceably above the substrate.

11. The placement apparatus according to claim 9, wherein the gripping unit has a gripping finger (34) which is displaceable in the x, y and z directions and rotatable about the z direction, wherein the gripping finger is configured to pick up the component, to rotate it about the z direction, and to deposit it on the target region.

12. The placement apparatus according to claim 9, characterized in that the first image acquisition system and the second image acquisition system are provided by a separate camera in each case.
